(19) United States
(12) Patent Application Publication
(10) Pub. No.: US 2013/0250585 A1
(43) Pub. Date: Sep. 26, 2013

(54) LED PACKAGES FOR AN LED BULB

(71) Applicants: Ronan Le Toquin, Fremont, CA (US); David Horn, Saratoga, CA (US)

(72) Inventors: Ronan Le Toquin, Fremont, CA (US); David Horn, Saratoga, CA (US)

(73) Assignee: Switch Bulb Company, Inc., San Jose, CA (US)

(21) Appl. No.: 13/619,890

(22) Filed: Sep. 14, 2012

Related U.S. Application Data
(60) Provisional application No. 61/535,356, filed on Sep. 15, 2011.
(60) Provisional application No. 61/569,191, filed on Dec. 9, 2011.
(60) Provisional application No. 61/579,626, filed on Dec. 22, 2011.
(60) Provisional application No. 61/585,231, filed on Jan. 10, 2012.
(60) Provisional application No. 61/585,226, filed on Jan. 10, 2012.
(60) Provisional application No. 61/682,163, filed on Aug. 10, 2012.

(51) Int. Cl. F21V 29/00; H01L 33/08

(52) U.S. Cl. CPC F21V 29/248; H01L 33/08
USPC 362/373; 438/28

(57) ABSTRACT

A light-emitting diode (LED) bulb includes a base, a shell connected to the base, a thermally conductive liquid held within the shell, and one or more support structures disposed within the shell. One or more LEDs are mounted to the one or more support structures and immersed in the thermally conductive liquid. The one or more LEDs each comprise a semiconductor die having at least one light-emitting interface and the one or more LEDs configured to emit light from the at least one light-emitting interface directly into the thermally conductive liquid.

### CROSS REFERENCE TO RELATED APPLICATIONS

This application claims the benefit under 35 U.S.C. 119(e) of prior copending U.S. Provisional Patent Application No. 61/535,356, filed Sep. 15, 2011; U.S. Provisional Patent Application No. 61/569,191, filed Dec. 9, 2011; U.S. Provisional Patent Application No. 61/579,626, filed Dec. 22, 2011; U.S. Provisional Patent Application No. 61/585,231, filed Jan. 10, 2012; U.S. Provisional Patent Application No. 61/585,226 filed Jan. 10, 2012; and U.S. Provisional Patent Application No. 61/682,163 filed Aug. 10, 2012, each of which is hereby incorporated by reference in the present disclosure in its entirety.

### BACKGROUND

1. Field

The present disclosure relates generally to light-emitting diode (LED) bulbs, and more specifically to structures for mounting an LED die within a liquid-filled shell of an LED bulb.

2. Description of Related Art

Traditionally, lighting has been generated using fluorescent and incandescent light bulbs. While both types of light bulbs have been reliably used, each suffers from certain drawbacks. For instance, incandescent bulbs tend to be inefficient, using only 2-3% of their power to produce light, while the remaining 97-98% of their power is lost as heat. Fluorescent bulbs, while more efficient than incandescent bulbs, do not produce the same warm light as that generated by incandescent bulbs. Additionally, there are health and environmental concerns regarding the mercury contained in fluorescent bulbs.

Thus, an alternative light source is desired. One such alternative is a bulb utilizing an LED. An LED comprises a semiconductor junction that emits light due to an electrical current flowing through the junction. Compared to a traditional incandescent bulb, an LED bulb is capable of producing more light using the same amount of power. Additionally, the operational life of an LED bulb is orders of magnitude longer than that of an incandescent bulb, for example, 10,000-100,000 hours as opposed to 1,000-2,000 hours.

While there are many advantages to using an LED bulb rather than an incandescent or fluorescent bulb, LEDs have a number of drawbacks that have prevented them from being as widely adopted as incandescent and fluorescent replacements. One drawback is that an LED, being a semiconductor, generally cannot be allowed to get hotter than approximately 120° C. As an example, A-type LED bulbs have been limited to very low power (i.e., less than approximately 8 W), producing insufficient illumination for incandescent or fluorescent replacements.

One approach to alleviating the heat problem of LED bulbs is to attach the LED to a conductive heat sink. To facilitate thermal conduction, it may be advantageous to thermally couple the LED to the heat sink in a way that minimizes thermal resistance. However, traditional LED mounting techniques require multiple layers and interfaces that increase the thermal resistance between the LED and the heat sink.

As shown in one example depicted in FIG. 1, there are several layers between an LED die 102 and a heat sink 110. In this example, LED die 102 is mounted to a package substrate 103. The package substrate 103 may be an Al₂O₃ or AlN lead frame used as an electrical interface to the LED die 102. The package substrate 103 also serves as the physical mount for the LED die 102. The package substrate 103 is bonded to a flexible circuit 106. In some cases, another type of direct chip attachment (DCA) substrate (e.g., glass or printed circuit board) is used in place of the flexible circuit 106. The package substrate 103 may be attached to the flexible circuit 106 using an adhesive layer, such as a polyimide adhesive having suitable properties. In some cases, the adhesive may be an insulator or a conductor depending on whether an electrical connection is to be made between the package substrate 103 and the flexible circuit 106.

In this example, the flexible circuit 106 is attached to a coupon 108. In some cases, the coupon 108 stabilizes the flexible circuit 106 and package substrate 103 during the assembly process. The flexible circuit may be attached to the coupon 108 using an adhesive layer. The coupon 108 is typically an aluminum metal plate having a thickness of approximately 1 mm to 2 mm. One face of the coupon 108 is mounted to heat sink 110 using another adhesive layer. The heat sink 110 is typically a thermally conductive material that is thick enough to conduct heat produced by the LED die 102.

As shown in FIG. 1, a typical implementation may include multiple layers and multiple interfaces between the LED die 102 and the heat sink 110. Each layer and interface increases the thermal resistance at least some amount.

Another drawback to using an LED is that light may be reflected back into the LED at the interface between the emitting face of the LED die and the surrounding medium. Typically, an LED has an index of refraction of approximately 2.2. If an LED die is mounted in air (having an index of refraction of approximately 1.0), as much as 20% of the light produced by the LED die may be reflected back at the interface between the LED die and the air.

As shown in FIG. 1, one solution to this problem is to embed the LED die 102 in a lens 105 having an index of refraction somewhere between the LED die (2.2) and the air (1.0) to reduce the back reflection and improve efficiency. However, as shown in FIG. 1, using traditional lens mounting techniques requires additional components (e.g., package substrate 103 and lens 105) that may impair the optical properties and/or the ability to conduct heat away from the LED die 102. In some cases, the LED die 102, package substrate 103, and lens 105 are manufactured as a single component sometimes referred to as an LED package 107.

The embodiments described herein can be used to improve thermal conduction and optical performance by mounting an LED die in an LED bulb that is filled with a thermally conductive liquid.

### SUMMARY

In one exemplary embodiment, a light-emitting diode bulb includes a base, a shell connected to the base, a thermally conductive liquid held within the shell, and one or more support structures disposed within the shell. One or more LEDs are mounted to the one or more support structures and are immersed in the thermally conductive liquid. The one or more LEDs each comprise a semiconductor die having at least one light-emitting interface and the one or more LEDs configured to emit light from the at least one light-emitting interface directly into the thermally conductive liquid.

In one exemplary embodiment, the LED bulb omits a lens disposed between the at least one light-emitting interface and the thermally conductive liquid. In one exemplary embodiment, the semiconductor die of each of the one or more LEDs is directly mounted to the one or more support structures.

### DESCRIPTION OF THE FIGURES

FIG. 1 depicts an LED die mounted to a package substrate with a lens.

FIG. 2 depicts a liquid-filled LED bulb.

FIG. 3 depicts an exemplary mounting for an LED die.

FIG. 4 depicts an exemplary mounting for an LED die.

FIG. 5 depicts an exemplary mounting for an LED die.

FIGS. 6A and 6B depict a liquid-filled LED bulb.

FIG. 7 depicts an exemplary mounting for an LED die.

FIG. 8 depicts an exemplary mounting for an LED die.

FIG. 9 depicts an exemplary mounting for an LED die.

FIG. 10 depicts a liquid-filled LED bulb.

FIG. 11 depicts an exemplary mounting for an LED die.

FIG. 12 depicts an exemplary mounting for an LED die.

FIG. 13 depicts an exemplary mounting for an LED die.

FIGS. 14A and 14B depict an exemplary flexible circuit for mounting an LED die.

FIG. 15 depicts an exemplary mounting for an LED with a phosphor.

FIGS. 16A and 16B depict exemplary results of an LED die emitting light directly into a thermally conductive liquid.

### DETAILED DESCRIPTION

The following description is presented to enable a person of ordinary skill in the art to make and use the various embodiments. Descriptions of specific devices, techniques, and applications are provided only as examples. Various modifications to the examples described herein will be readily apparent to those of ordinary skill in the art, and the general principles defined herein may be applied to other examples and applications without departing from the spirit and scope of the various embodiments. Thus, the various embodiments are not intended to be limited to the examples described herein and shown, but are to be accorded the scope consistent with the claims.

Various embodiments are described below relating to LED bulbs. As used herein, an “LED bulb” refers to any light-generating device (e.g., a lamp) in which at least one LED is used to generate light. Thus, as used herein, an “LED bulb” does not include a light-generating device in which a filament is used to generate the light, such as a conventional incandescent light bulb. It should be recognized that the LED bulb may have various shapes in addition to the bulb-like A-type shape of a conventional incandescent light bulb. For example, the bulb may have a tubular shape, a globe shape, or the like. The LED bulb of the present disclosure may further include any type of connector; for example, a screw-in base, a dual-prong connector, a standard two- or three-prong wall outlet plug, bayonet base, Edison Screw base, single-pin base, multiple-pin base, recessed base, flanged base, grooved base, side base, or the like.

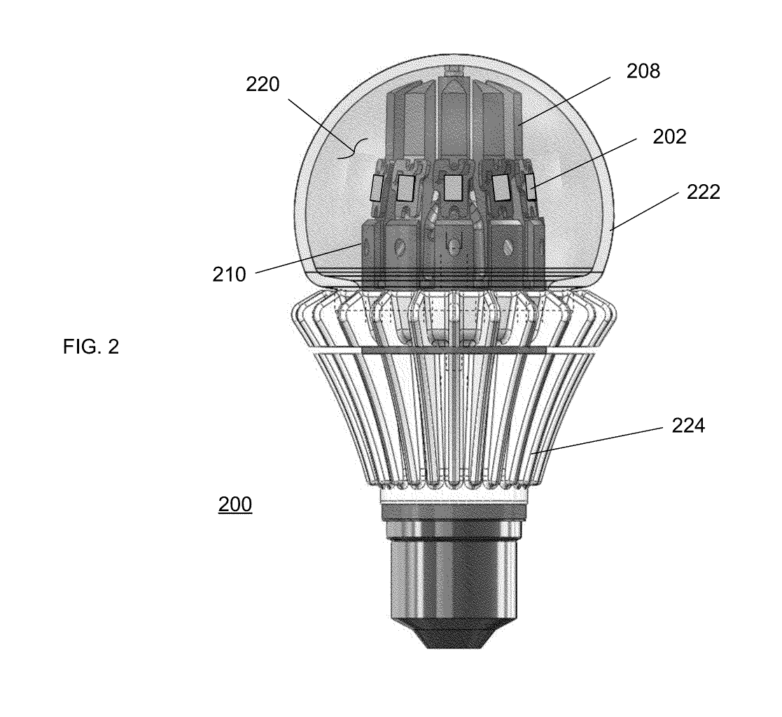

FIG. 2 depicts an exemplary LED bulb 200. For convenience, all examples provided in the present disclosure describe and show LED bulb 200 being a standard A-type form factor bulb. However, as mentioned above, it should be appreciated that the present disclosure may be applied to LED bulbs having any shape, such as a tubular bulb, a globe-shaped bulb, or the like.

In some embodiments, LED bulb 200 may use 6 W or more of electrical power to produce light equivalent to a 40 W incandescent bulb. In some embodiments, LED bulb 200 may use 20 W or more to produce light equivalent to or greater than a 75 W incandescent bulb. Depending on the efficiency of the LED bulb 200, between 4 W and 16 W of heat energy may be produced when the LED bulb 200 is illuminated.

LED bulb 200 includes a shell 222 and base 224, which interact to form an enclosed volume 220 over one or more LED dies 202. The enclosed volume 220 is filled with a thermally conductive liquid. As shown in FIG. 2, the base 224 includes an adaptor for connecting the bulb to a lighting fixture. In some cases, the shell 222 and base 224 have a form factor similar to an A-type shape of a conventional incandescent light bulb.

Shell 222 may be made from any transparent or translucent material such as plastic, glass, polycarbonate, or the like. Shell 222 may include dispersion material spread throughout the shell to disperse light generated by LED dies 202. The dispersion material prevents LED bulb 200 from appearing to have one or more point sources of light. The shell 222 may also be coated or treated to diffuse the light produced by the LED dies 202.

LED bulb 200 includes a plurality of LED dies 202 mounted in a radial pattern within the shell 222. Each of the LED dies 202 includes at least one semiconductor die having at least one light-emitting interface. Each of the plurality of LED dies 202 is attached to a support structure 208 of a heat sink 210 and is immersed in the thermally conductive liquid. The support structures 208 and heat sink 210 may be made of any thermally conductive material, such as aluminum, copper, brass, magnesium, zinc, or the like. Since the support structures 208 and heat sink 210 are formed from a thermally conductive material, heat generated by LED dies 202 may be conductively transferred to the support structures 208 and heat sink 210. The support structures 208 and heat sink 210 are at least partially immersed in the thermally conductive liquid and, therefore, are able to dissipate heat to the thermally conductive liquid. The support structures 208 are adapted to mount LED dies 202 on a side mounting face, as shown in FIG. 2. The support structures 208 have channels or openings between each support structure 208 to allow the passage of liquid. Example support structures 208 may include, but are not limited to, finger-shaped protrusions or posts. In another embodiment, LED dies 202 may be mounted on a top mounting face of the support structures 208.

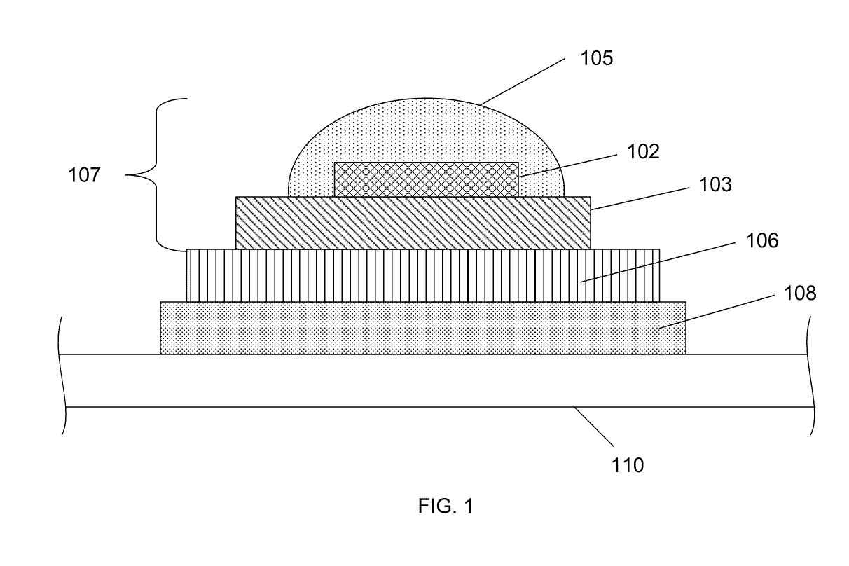

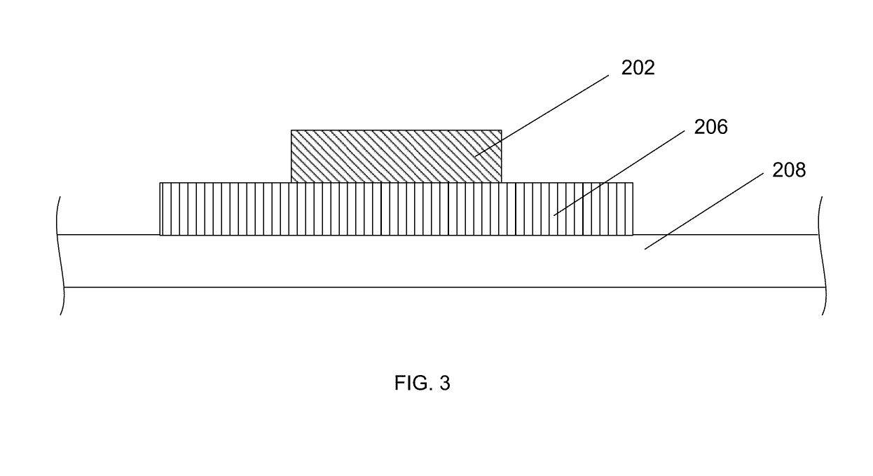

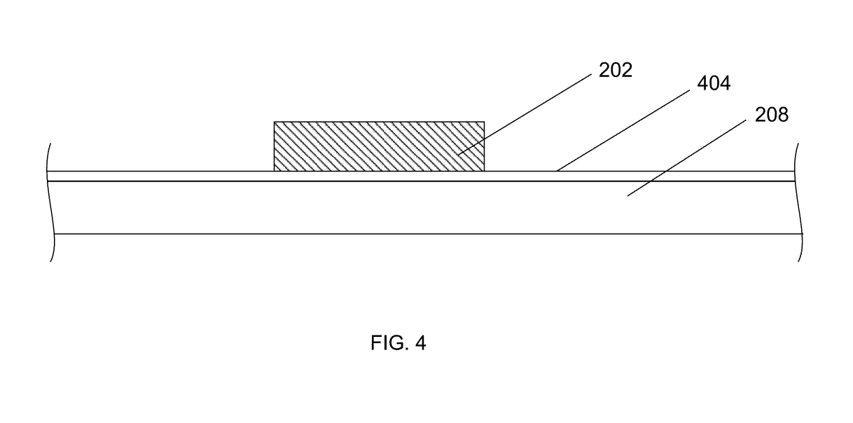

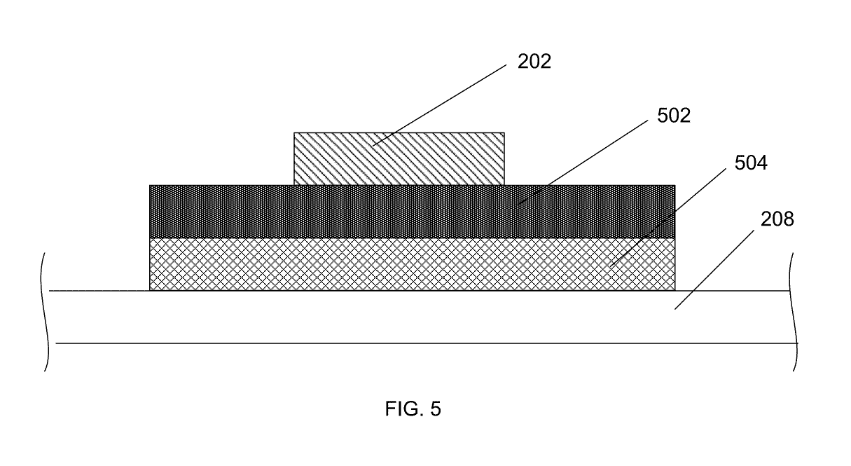

The LED dies 202 can be mounted to the support structures 208 of the heat sink 210 using a variety of techniques that reduce the number of thermal interfaces, as compared to the example discussed with respect to FIG. 1, above. The mounting technique illustrated in FIG. 2 most closely correlates to the LED die mounting shown in FIG. 3, discussed in more detail below. FIGS. 4 and 5, also discussed in more detail below, depict alternative LED die mounting techniques. Generally, the LED die mounting techniques shown in FIGS. 3, 4, and 5 reduce the number of thermal barriers as compared to the LED die mounting shown in FIG. 1. The reduction in thermal barriers may increase the cooling efficiency of the support structures 208 and heat sink 210 and allow for a smaller and more economical heat sink 210 and support structures 208. Additionally, increasing the thermal efficiency of the support structures 208 and heat sink 210 may allow the LED dies 202 to be driven at a higher current and produce more light.

As discussed above, shell 222 and base 224 of LED bulb 200 interact to define an enclosed volume 220 filled with a thermally conductive liquid. As used herein, the term “liquid” refers to a substance capable of flowing. Also, the substance used as the thermally conductive liquid is a liquid or at the liquid state within, at least, the operating, ambient-temperature range of the bulb. An exemplary temperature range includes temperatures between −40° C. to +40° C. The thermally conductive liquid may be mineral oil, silicone oil, glycols (PAGs), fluorocarbons, or other material capable of flowing. In the examples discussed below, 20 cSt viscosity polydimethylsiloxane (PDMS) liquid sold by Clearco is used as a thermally conductive liquid. It may be desirable to have the liquid chosen be a non-corrosive dielectric. Selecting such a liquid can reduce the likelihood that the liquid will cause electrical shorts and reduce damage done to the components of LED bulb 200.

As described above, the thermally conductive liquid is able to transfer heat away from the LED dies 202, the support structures 208, and heat sink 210. Typically, the thermally conductive liquid transfers the heat via conduction and passive convection to other components of the LED bulb 200, including the shell 222 and base 224. When the thermally conductive liquid is used in combination with the LED die mounting techniques described herein, heat can be removed from the LED dies 202 more efficiently, as compared to the multilayered configuration shown in FIG. 1. Specifically, by reducing the number of thermal barriers between the LED dies 202 and the support structures 208, and immersing the LED dies 202 and support structures 208 in a thermally conductive liquid and allowing for conductive and passive convective cooling, the overall heat transfer may be significantly improved when compared to the LED die mounting technique shown in FIG. 1. This is particularly true as compared to the LED die mounting technique shown in FIG. 1, which is typically implemented in an open air configuration (without a thermally conductive liquid).

As a result of the heat transfer, the temperature of portions of the thermally conductive liquid is typically above the ambient or room temperature. The increase in temperature depends on the number of LED dies 202, the total wattage of the LED bulb 200 and the physical configuration of components of the LED bulb 200. The elevated temperatures of the thermally conductive liquid near the LED dies 202 may facilitate passive convective flow within the thermally conductive liquid. Generally, increases in passive convective flow increase the heat transfer capacity of the LED bulb 200.

Also, as described above, the thermally conductive liquid acts as an optical medium by transmitting the light emitted from the LED dies 202 to the translucent shell 222. By using a thermally conductive liquid, as shown in FIG. 2, an LED die 202 can be used without using a lens 105 or equivalent structures (as shown in, for example, FIG. 1). In this example, LED dies 202 may emit light directly into the thermally conductive liquid.

For purposes of the description of the embodiments herein, a lens is considered to be any component made from a solid translucent material that is capable of directing or focusing rays of light. A lens may be formed from a glass or plastic material having at least two refracting surfaces. Either or both of the refracting surfaces may be curved to form either a convex or concave shape such that light entering one of the refracting surfaces is directed or focused in a prescribed direction. In some cases, the lens may be tinted, colored, or include a dispersion material. For purposes of this discussion, a phosphor coating or other photoluminescent material, by itself, is not considered a lens.

With reference to FIG. 1, the lens 105 can be omitted if, for example, the LED die 202 is configured to emit light directly into a thermally conductive liquid having an index of refraction somewhere between the index of refraction of the LED dies 202 and the surrounding medium. In one example, an LED die 202 has an index of refraction of approximately 2.2. The bulb 200 may be surrounded by an air medium having an index of refraction of approximately 1.0. In this case, the thermally conductive liquid is selected to have an index of refraction between 2.2 and 1.0. In some implementations, the index of refraction of the thermally conductive liquid is approximately 1.4. The shell 222 is also selected to have an index of refraction between 2.2 and 1.0. In some cases, the shell 222 has an index of refraction lower than the index of refraction of the thermally conductive liquid but greater than air.

Another benefit of an LED die emitting light directly into the thermally conductive liquid is that the light's transition to air (with an index of refraction of 1.0) is moved further away from the LED die. The further away the transition to air occurs, the higher the chance that reflected light will be reflected back to a surface that will not absorb the light but will instead reflect the light out of the bulb. For example, reflected light hitting support structures 208 and/or heat sink 210 has a higher chance of being reflected back out of the bulb as compared to light reflecting back on the LED dies 202. By moving transitions from one index of refraction to another index of refraction further away from LED dies 202, reflected light may have a lower chance of being absorbed by LED dies 202.

In general, an LED die can be configured to emit light directly into the thermally conductive liquid and also be coated with a phosphor or photoluminescent material used to produce a particular color light emission. By using a thermally conductive liquid having an index of refraction between the index of refraction of a coated LED die and the shell, the back reflection at the interface between the surface of the coated LED die and the thermally conductive liquid can be reduced (as compared to an LED die-to-air or an LED die-to-lens interface). In other words, less of the light produced by the LED and phosphor combination will be reflected back and absorbed by the LED die.

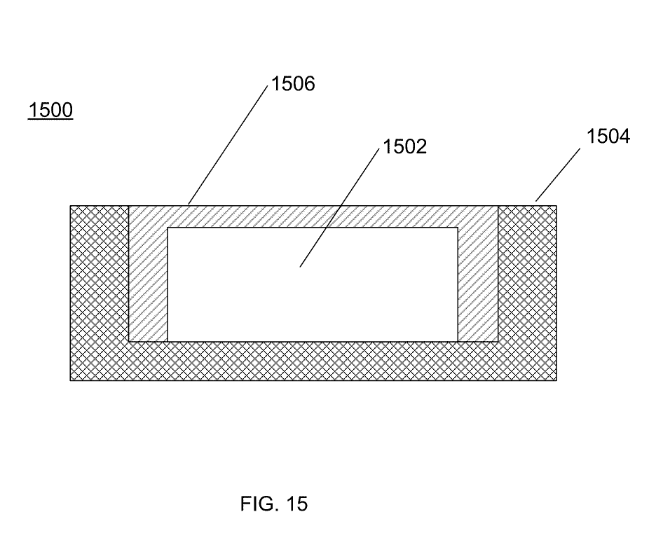

One exemplary configuration of a phosphor-coated LED 1500 is depicted in FIG. 15. As shown in FIG. 15, an LED die 1502 is mounted to an encapsulant 1504 and coated with a phosphor 1506. The encapsulant 1504 may be made from a variety of materials including, for example, a liquid crystal polymer (LCP) or a hybrid material including a silicone-epoxy polymer. As shown in FIG. 15, the encapsulant 1504 is open on at least one side and does not include a lens or equivalent structure. As a result, the phosphor-coated LED 1500 may emit light directly into the thermally conductive liquid.

In general, the phosphor-coated LED 1500 shown in FIG. 15 can be used in place of the LED die (e.g., 202 or 1002) depicted in any of the embodiments described herein. In some cases, a phosphor-coated LED includes more than one LED die mounted within the same encapsulant. In some cases, the phosphor-coated LED is configured with electrical leads to facilitate the electrical connection between one or more LED dies and a flexible circuit.

One advantage to implementing a phosphor-coated LED that is configured to emit light directly into the thermally conductive liquid is that the color of the emitted light is shifted, as compared to a phosphor-coated LED configured to emit light into an air medium or through a lens mounted to the face of the LED. As discussed above, emitting light directly into a thermally conductive liquid reduces back reflection into the LED die. In some cases, a color shift may be due, in part, to the LED die absorbing a disproportionate amount of blue light. By reducing the back reflection into the LED die, the amount of blue light that is emitted may be increased and result in a color shift of the emitted light.

The resulting color shift may allow for the use of alternative phosphor combinations. For example, the resulting color shift may expand the range of alternative phosphor combinations that may have been considered unacceptable for traditional lighting applications (when configured to emit light into an air medium or through a lens). These alternative phosphor combinations may be less expensive or have improved availability, as compared to phosphor-coated LEDs that are used in traditional lighting applications.

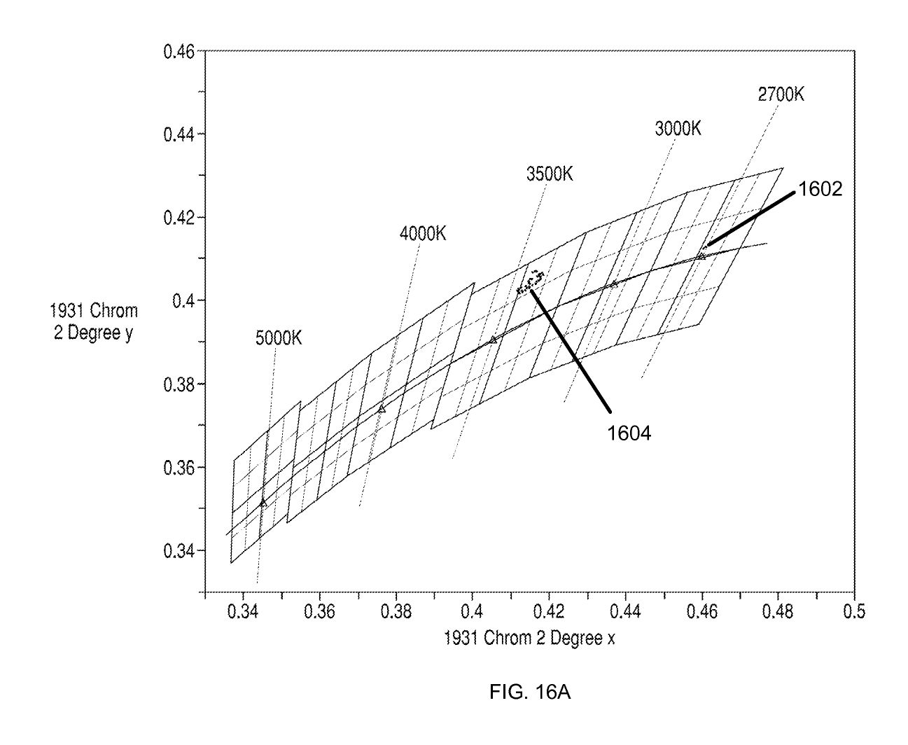

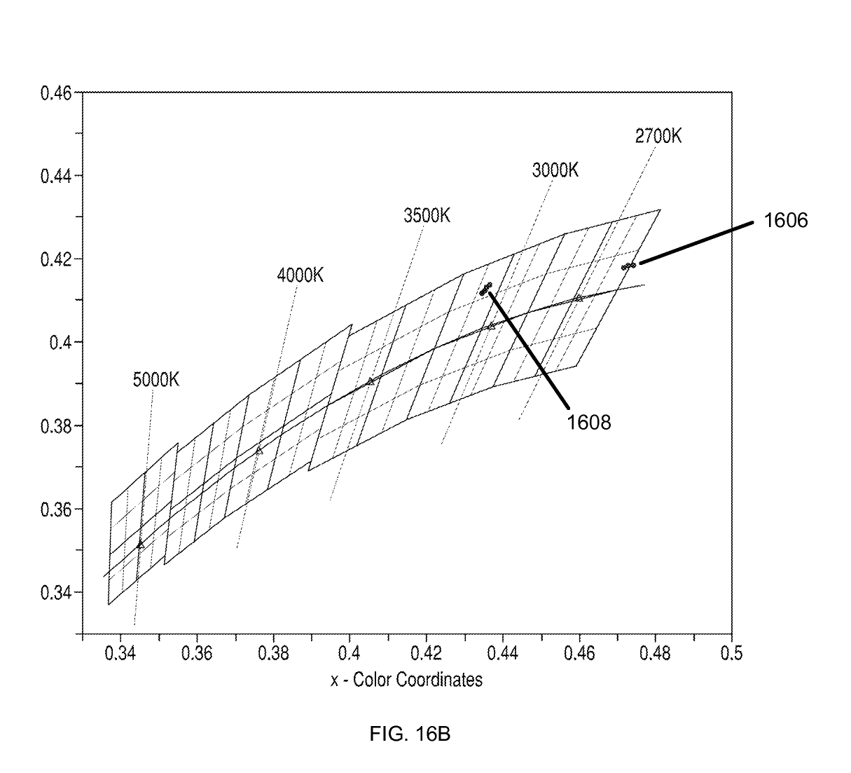

FIGS. 16A and 16B depict predicted exemplary color emissions for a phosphor-coated LED emitting light directly into a thermally conductive liquid as compared to an emission directly into an air medium. The predicted color emission directly into an air medium may also roughly correspond to the color emission through a lens attached to the light-emitting face of the phosphor-coated LED. The predicted light emission colors depicted in FIGS. 16A and 16B are mapped to an Ccx-Ccy color space with respect to a black-body temperature measured in degrees Kelvin.

FIG. 16A depicts a phosphor-coated LED (Nichia NSL2757) configured to emit light having a black-body color temperature of approximately 2,700 degrees Kelvin when emitting directly into an air medium. The predicted color emission is designated by point 1602. When the same phosphor-coated LED emits light directly into a thermally conductive liquid (without an intermediate lens or equivalent structure), the emitted light has a predicted black-body color temperature of approximately 3,400 degrees Kelvin, designated by point 1604. Thus, a color shift of approximately 700 degrees Kelvin can be achieved by emitting light directly into a thermally conductive liquid.

FIG. 16B depicts another phosphor-coated LED (Nichia NFSL157AT-H3) configured to emit light having a black-body color temperature of approximately 2,580 degrees Kelvin when emitting directly into an air medium. The predicted color emission is designated by point 1606. When the same phosphor-coated LED emits light directly into a thermally conductive liquid (without an intermediate lens or equivalent structure), the emitted light has a black-body color temperature of approximately 3,070 degrees Kelvin, designated by point 1608. Thus, a color shift of approximately 490 degrees Kelvin can be achieved by emitting light directly into a thermally conductive liquid.

### 1. LED Die Mounting

FIG. 3 depicts an LED die mounting technique for mounting an LED die in a liquid-filled LED bulb. In FIG. 3, the LED die 202 is mounted directly to a flexible circuit 206. The LED die 202 is bonded to the flexible circuit 206 using either an electrically insulating or conductive adhesive. Electrical connections are made to the flexible circuit 206 by reflowing a metal alloy that is electrically connected to the LED die 202 and to connections on a surface of the flexible circuit 206. Additionally or alternatively, the LED die 202 can be electrically connected to the flexible circuit 206 using wire bonding techniques. In FIG. 3, the flexible circuit 206 is attached to the support structure 208. The flexible circuit 206 may be attached to the support structure 208 using an adhesive or mechanical-bonding technique.

In the example shown in FIG. 3, only two thermal interfaces are required: a first between the LED die 202 and the flexible circuit 206 and a second between the flexible circuit 206 and the support structure 208. The reduction in the number of thermal interfaces (as compared to FIG. 1) provides improved heat transfer from LED die 202 to support structure 208. The reduced number of parts may also reduce cost and simplify manufacturing.

For example, the LED mounting technique of FIG. 3 may result in a thermal resistance from the LED die to the heat sink of approximately 5-6° C./W. This is a significant improvement over the mounting technique shown in FIG. 1, which may result in a thermal resistance from the LED die to the heat sink of approximately 12-15° C./W.

The mounting technique shown in FIG. 3 also omits the lens 105 shown in FIG. 1. As explained above, because the LED die 202 is immersed in the thermally conductive liquid when installed in a liquid-filled LED bulb, a traditional lens 105, acting as an intermediate medium between the LED die and the air, is not necessary. As a result, LED dies 202 may emit light directly into the thermally conductive liquid.

FIG. 4 depicts an alternative LED die mounting technique for mounting an LED die in a liquid-filled LED bulb. In FIG. 4, the LED die 202 is mounted directly to a support structure 208. If the support structure 208 is made from an electrically conductive material, such as aluminum or copper, an insulating dielectric layer 404 may be attached or applied to the surface of the support structure 208. The LED die 202 is bonded to the support structure 208 and/or dielectric layer 404 using either an electrically insulating or conductive adhesive. Electrical connections are made to the LED die 202 using traces embedded in the support structure 208.

FIG. 5 depicts an alternative LED die mounting technique for mounting an LED die in a liquid-filled LED bulb. In FIG. 5, the LED die 202 is mounted to a conductive layer 502. The conductive layer 502 is mounted to a dielectric or insulating layer 504. The dielectric layer is attached to a surface of the support structure 208. The components shown in FIG. 5 can be bonded using one or more adhesives.

For many of the same reasons discussed above with respect to FIG. 3, the heat transfer and optical properties of the alternative mounting technique shown in FIGS. 4 and 5 may also be advantageous as compared to the LED mounting shown in FIG. 1.

### 2. LED Die Mounting Using Thermally Conductive Structures

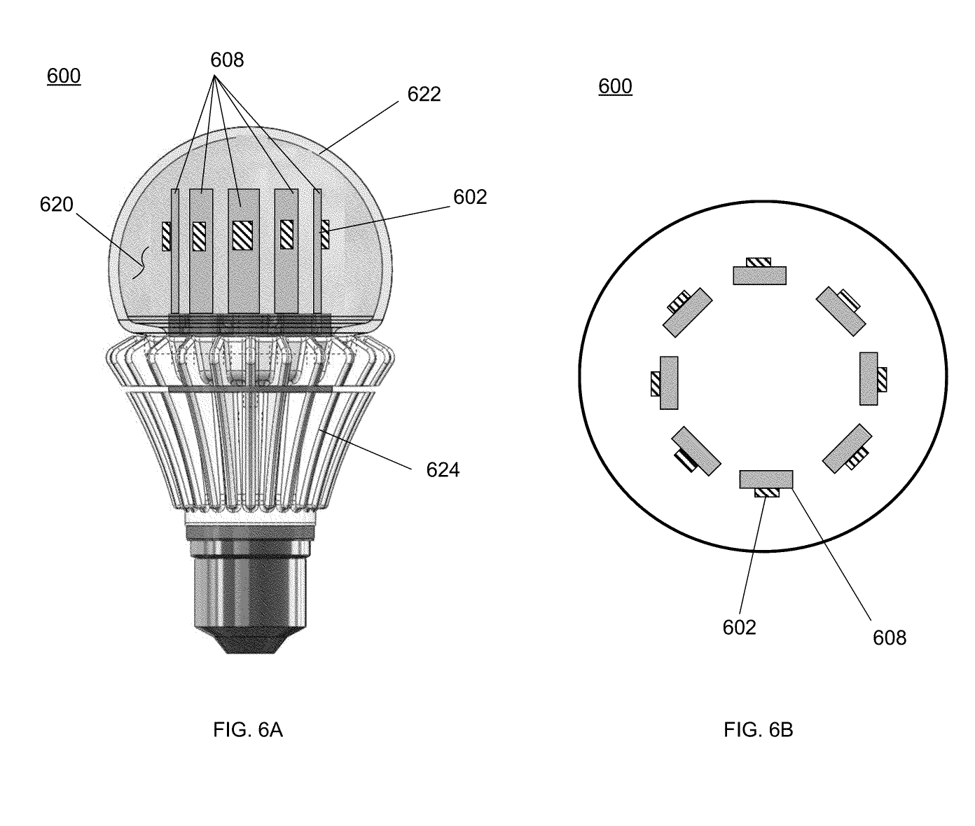

FIGS. 6A and 6B depict a side view and a top view of a liquid-filled LED bulb 600 having conducting support structures 608 instead of support structures 208 of a heat sink 210 (as shown in FIG. 2). Similar to the LED bulb 200 of FIG. 2, the LED bulb 600 has a base 624 connected to a shell 622 that surrounds the LED dies 602. The support structures 608 of the LED bulb 600 are mechanically and thermally connected to the base 624. The shell 622 and base 624 interact to form an enclosed volume 620. The enclosed volume 620 is filled with a thermally conductive liquid. The thermally conductive liquid removes heat from the LED dies 602 and support structures 608 via conduction and convection.

In some embodiments, the LED dies 602 are electrically connected together with a single flexible circuit. In an exemplary embodiment, a single flexible circuit is bonded to the support structures 608 and is used to mount the individual LED dies 602.

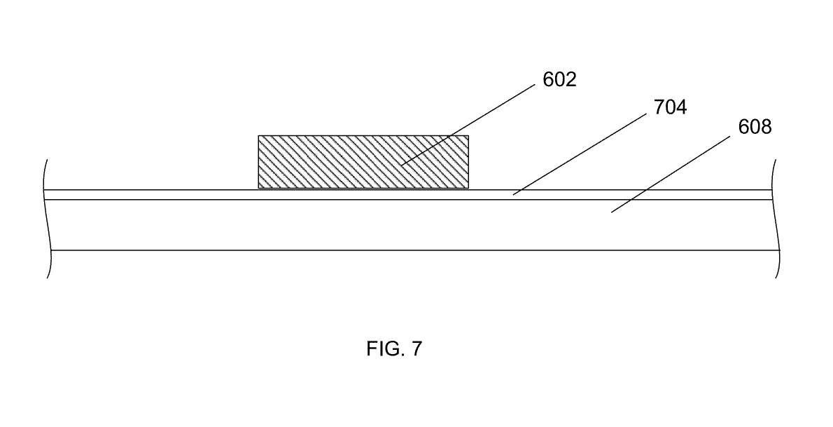

FIGS. 7, 8, and 9 depict alternative embodiments of LED die mounting techniques with thermally conductive support structures.

FIG. 7 depicts an exemplary LED die mounting technique for mounting an LED die in a liquid-filled LED bulb, such as the liquid-filled LED bulb 600 shown in FIGS. 6A and 6B. In FIG. 7, the LED die 602 is mounted directly to a support structure 608. If the support structure 608 is made from an electrically conductive material, such as aluminum or copper, an insulating dielectric layer 704 may be attached or applied to the surface of the support structure 608. The LED die 602 is bonded to the support structure 608 and/or dielectric layer 704 using either an electrically insulating or conductive adhesive. Electrical connections are made to the LED die 602 with a reflowed metal alloy or wire bonds electrically contacting traces embedded in the support structure 608.

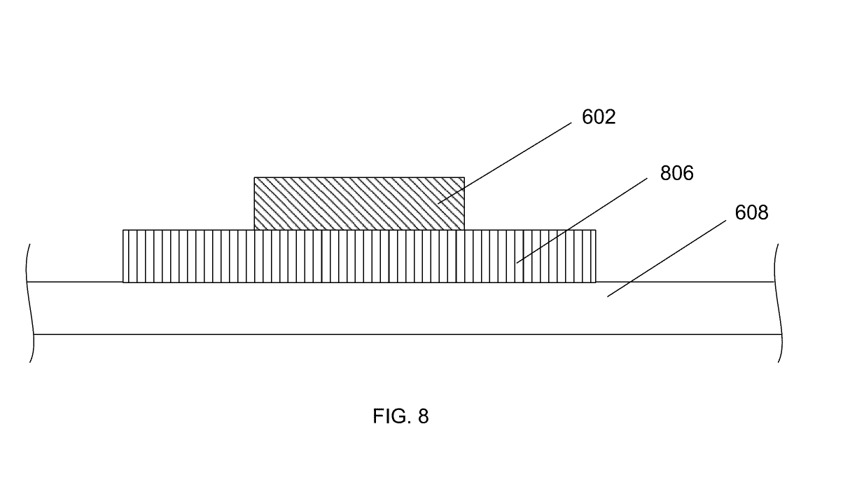

FIG. 8 depicts an LED die mounting technique for mounting an LED die in a liquid-filled LED bulb. In FIG. 8, the LED die 602 is mounted directly to a flexible circuit 806. The LED die 602 is bonded to the flexible circuit 806 using either an electrically insulating or conductive adhesive. Electrical connections are made to the flexible circuit 806 by reflowing a metal alloy that is electrically connected to the LED die 602 and to connections on a surface of the flexible circuit 806. Additionally or alternatively, the LED die 602 can be electrically connected to the flexible circuit 806 using wire bonding techniques. In FIG. 8, the flexible circuit 806 is attached to the support structure 608. The flexible circuit 806 may be attached to the support structure 608 using an adhesive or mechanical bonding technique.

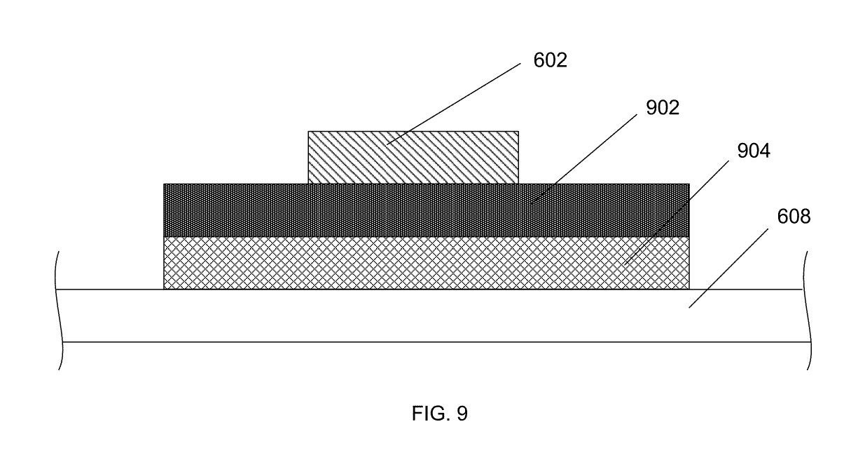

FIG. 9 depicts an alternative LED die mounting technique for mounting an LED die in a liquid-filled LED bulb. In FIG. 9, the LED die 602 is mounted to a conductive layer 902. The conductive layer 902 is mounted to a dielectric or insulating layer 904. The dielectric layer 904 is attached to a surface of the support structure 608. The components shown in FIG. 9 can be bonded using one or more adhesives.

The exemplary mounting techniques for the LEDs discussed above with respect to FIGS. 7, 8, and 9 may occur prior to attaching the support structures 608 to base 624 (FIG. 6A). For example, LED dies 602 may be mounted to support structures 608. Then, each support structure 608 with a mounted LED die 602 may be attached to base 624 using, for example, a screw, an adhesive or a spot weld. In other cases, support structures 608 may be clamped in place to base 624.

For many of the same reasons discussed above with respect to FIG. 3, the heat transfer and optical properties of the alternative mounting techniques shown in FIGS. 7, 8, and 9 may also be advantageous as compared to the LED mounting shown in FIG. 1.

### 3. LED Die Mounting Using Thermally Conductive Structures

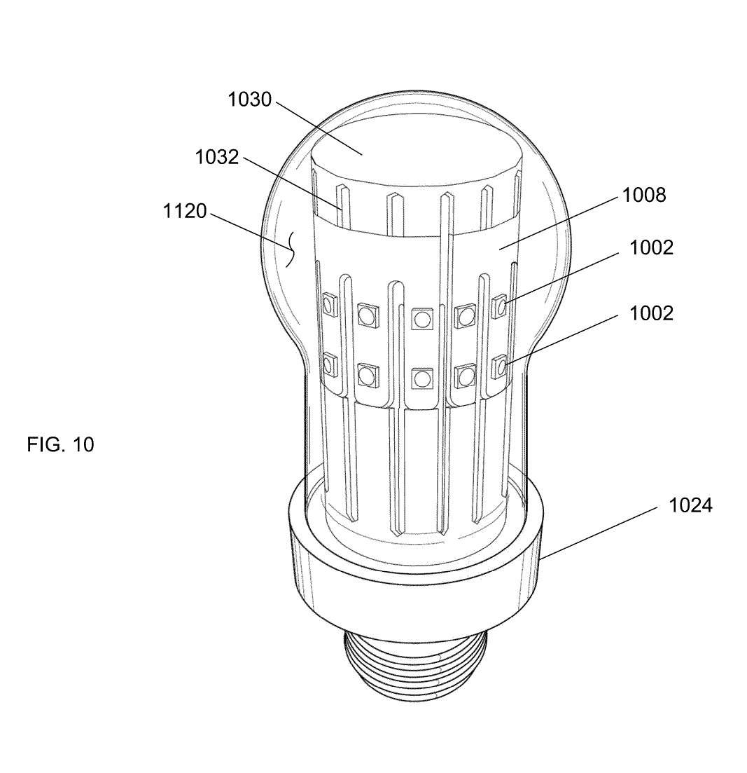

FIG. 10 depicts a liquid-filled LED bulb 1000 having a cylindrical support structure 1008 for mounting LEDs 1002. Similar to the LED bulb 200 of FIG. 2, the LED bulb 1000 has a base 1024 connected to a shell 1022 that surrounds the LEDs 1002. The support structures 1008 of the LED bulb 1000 are mechanically and thermally connected to the base 1024. The shell 1022 and base 1024 interact to form an enclosed volume 1020. The enclosed volume 1020 is filled with a thermally conductive liquid. The thermally conductive liquid removes heat from the LEDs 1002 and support structures 1008 via conduction and convection.

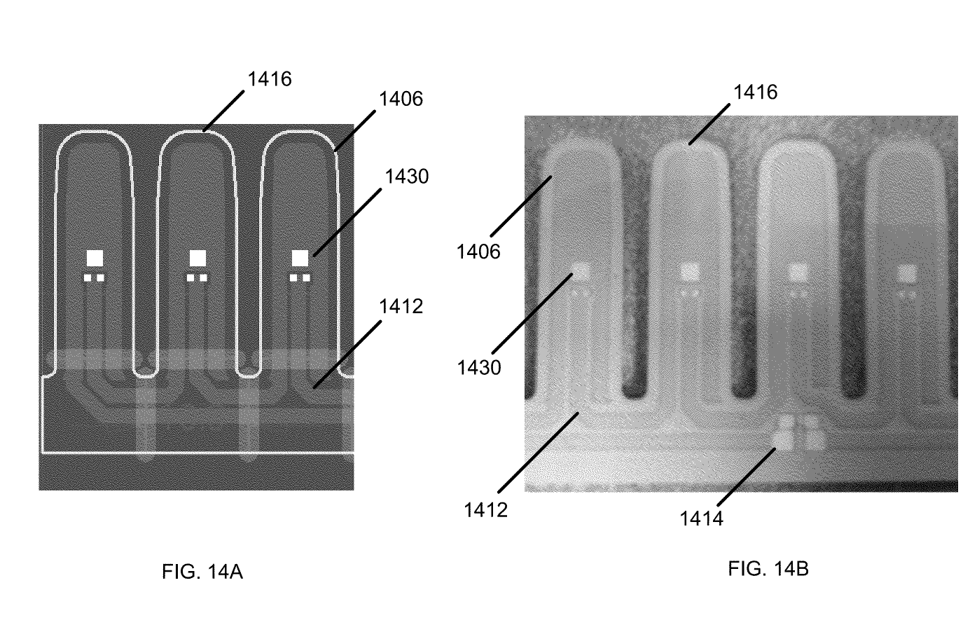

In the present embodiment, the support structure 1008 is a composite laminate structure including a flexible circuit laminated to a thermally conductive support material. As discussed in more detail below with respect to FIGS. 14A and 14B, the composite laminate structure may include any thermally conductive structural material, such as aluminum, copper, brass, magnesium, zinc, or the like. The support structure 1008 includes multiple flange portions, each flange portion having an electrical connection for an LED 1002. The LEDs 1002 are electrically connected together with a single flexible circuit that is incorporated into the support structure 1008.

As shown in FIG. 10, the support structure 1008 is attached to a chassis 1030. In some cases, the support structures 1008 are attached to the chassis 1030 to form a mechanical and thermal bond between the two components. The chassis 1030 is attached to the base 1024 and may also be made from a thermally conductive material. The chassis 1030 includes multiple slotted portions 1032 to allow the passage of the thermally conductive liquid.

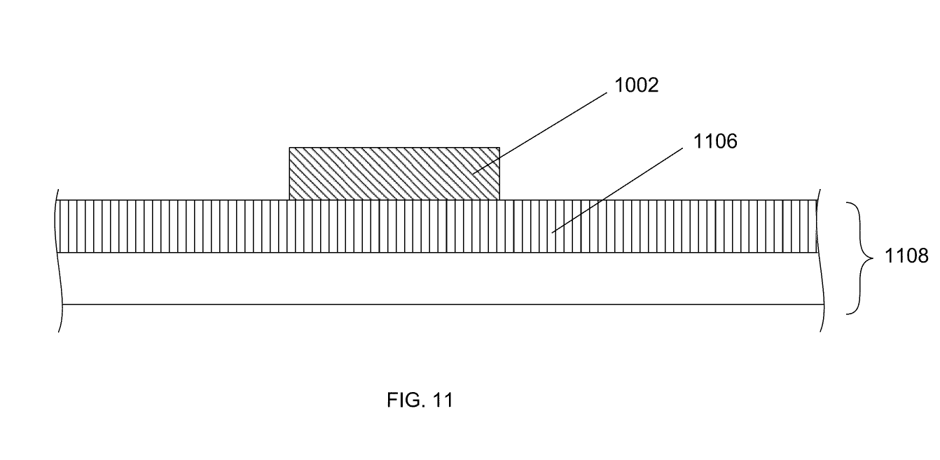

FIGS. 11, 12, and 13 depict alternative embodiments of LED die mounting techniques with thermally conductive support structures.

FIG. 11 depicts an LED mounting technique for mounting an LED die in a liquid-filled LED bulb. In FIG. 11, the LED die 1002 is mounted directly to a flexible circuit 1106. The LED die 2002 is bonded to the flexible circuit 1106 using either an electrically insulating or conductive adhesive. Electrical connections are made to the flexible circuit 1106 by reflowing a metal alloy that is electrically connected to the LED die 1002 and to connections on a surface of the flexible circuit 1106. Additionally or alternatively, the LED die 2002 can be electrically connected to the flexible circuit 1106 using wire-bonding techniques. In FIG. 11, the flexible circuit 1106 is incorporated into the support structure 1108, which is formed from a composite laminate structure.

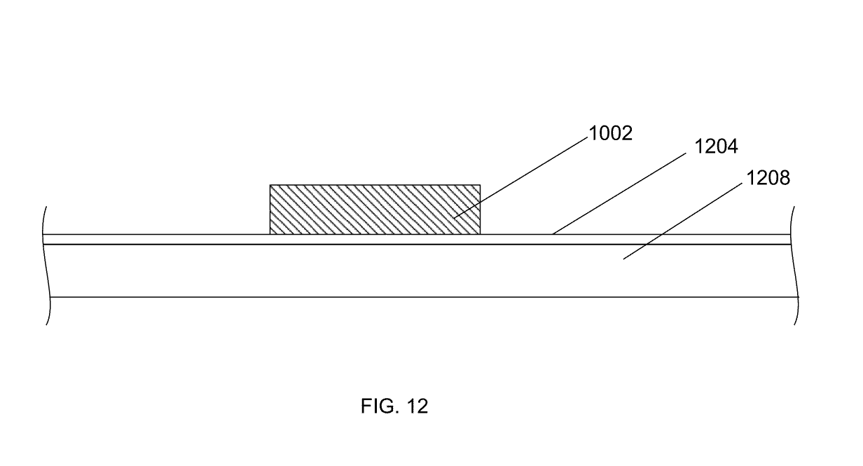

FIG. 12 depicts an exemplary LED mounting technique for mounting an LED 1002 in a liquid-filled LED bulb, such as the liquid-filled LED bulb 1000 shown in FIG. 10. In FIG. 12, the LED 1002 is mounted directly to a support structure 1208. If the support structure 1208 is made from an electrically conductive material, such as aluminum or copper, an insulating dielectric layer 1204 may be attached or applied to the surface of the support structure 1208. The LED 1002 is bonded to the support structure 1208 and/or dielectric layer 1204 using either an electrically insulating or conductive adhesive. Electrical connections are made to the LED die 1002 with a reflowed metal alloy or wire bonds electrically contacting traces embedded in the support structure 1208.

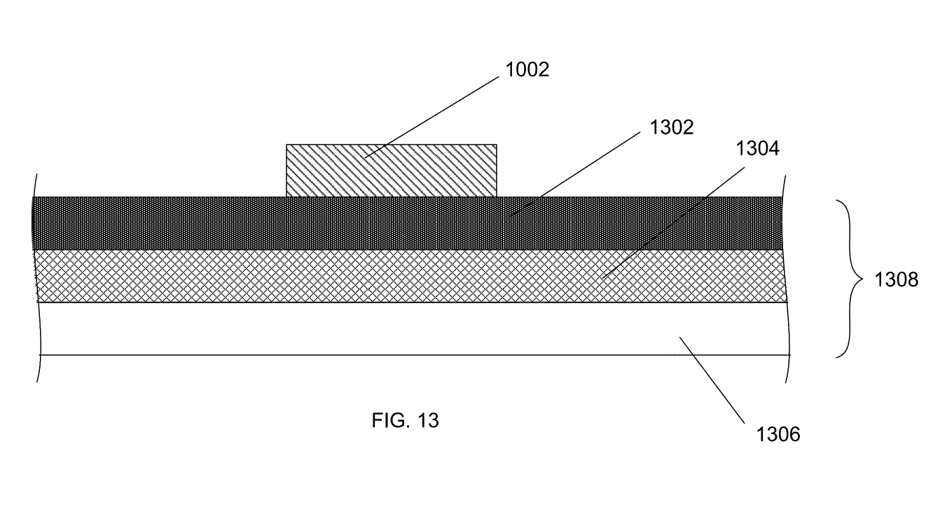

FIG. 13 depicts an alternative LED die mounting technique for mounting an LED die in a liquid-filled LED bulb. In FIG. 13, the LED die 1002 is mounted to a conductive layer 1302. The conductive layer 1302 is mounted to a dielectric or insulating layer 1304. The dielectric layer 1304 is attached to a surface of a mechanical support layer 1306. Layers 1302, 1304, and 1306 are incorporated into the support structure 1308, which is formed from a composite laminate structure.

For many of the same reasons discussed above with respect to FIG. 3, the heat transfer and optical properties of the alternative mounting techniques shown in FIGS. 11, 12, and 13 may also be advantageous as compared to the LED mounting shown in FIG. 1.

### 4. Electrical Interconnects Used as a Heat Spreader

In some variations of the embodiments described above with respect to FIGS. 2-13, the electrical interconnects (e.g., the flexible circuit, conductive layer, embedded traces, wire bonds, or the like) that deliver electrical current to the LEDs may be constructed using thermally conductive materials, such as copper, silver, aluminum, other metals, or other thermally and electrically conductive materials, for spreading heat from the LEDs and transferring the heat to the surrounding liquid. For example, electrical interconnects, such as embedded traces, a thermal bonding copper solder pad, or a backing layer of copper or aluminum, can be arranged to transfer heat from their surfaces directly into the liquid or can be arranged to transfer heat from their surfaces into the liquid through a covering of solder mask or a protective cover layer for electrical isolation of the underlying conductor. In this way, the heated electrical interconnects act as a direct heat transfer surface to the liquid (utilizing convection and conduction into the liquid).

FIGS. 14A and 14B depict an exemplary flexible circuit 1406 used as an electrical interconnect for mounting LED dies. The flexible circuit 1406 includes mounting pads 1430 for electrically connecting multiple LED dies. The mounting pads 1430 are electrically connected by conductive traces 1412, which terminate at bonding pads 1414. The bonding pads 1414 can be used to attach electrical lead wires or another type conductive element to receive power for the LED dies.

The materials used to construct the flexible circuit may also be thermally conductive. In some cases, the electrical conductors of the flexible circuit 1406 are configured to also conduct heat away from the LED dies. The thermally conductive materials may facilitate heat spreading from the LED dies to the surrounding liquid and to other components of the LED bulb.

Flexible circuit 1406 can be printed and cut using a flat sheet of flexible circuit material to form multiple flange portions 1416. LED dies can also be installed on the flexible circuit 1406 while the flexible circuit 1406 is flat. The flexible circuit 1406 can be formed into a cylindrical or conical shape. When the flexible circuit 1406 is formed into a cylindrical or conical shape, the LED dies are arranged in a radial pattern. The flange portions 1416 of the flexible circuit 1406 may also be attached to supports of a cylindrical or conical heat sink. (See, e.g., FIG. 2 depicting a cylindrical heat sink 210 with support structures 208 arranged in a radial pattern.)

The flexible circuit 1406 may also be incorporated into a composite laminate structure. In one example, the flexible circuit 1406 is laminated to a thermally conductive structural material that provides structural rigidity to the flexible circuit 1406. The composite laminate structure may include any thermally conductive structural material, such as aluminum, copper, brass, magnesium, zinc, or the like. The composite laminate structure may be formed as a laminate plate and then cut into the profile shape shown in FIGS. 14A and 14B. The composite laminate structure may then be formed into a cylindrical or conical shape and attached to another component of the LED bulb. Because the composite laminate structure may have structural rigidity, it may include relief portions and may be formed using a mandrel or other metal-forming tool.

FIGS. 14A and 14B depict one exemplary embodiment of a flexible circuit used as an electrical interconnect. As mentioned above, other types of electrical interconnects could also be used including conductive layers, embedded traces, wire bonds, or the like. In general, the surface area of the electrical interconnects near the LEDs (e.g., mounting pads 1430, electrical traces 1412) can be increased. For example, the width of the electrical interconnects can be increased, the surface of the electrical interconnects can be curved or textured, fin protrusions can be attached to the electrical interconnects, or other arrangements may be used to increase the surface area of the electrical interconnects near the LEDs.

Typically, the temperature of the electrical interconnects is higher in regions closer to the LED die. One advantage to increasing the surface area near the LED dies is that heat transfer between a heat sink and a thermally conductive liquid can be more efficient at higher temperatures. Thus, in order to increase the efficiency of heat transfer between the LED, electrical interconnects, and the thermally conductive liquid, the surface area of the electrical interconnects can be increased in areas having higher temperatures.

In some embodiments, the electrical interconnects can include metal layers laminated to flexible or rigid underlying dielectric materials (e.g., a composite laminate structure discussed above). The dielectric materials can also be laminated to additional metal layers or constructions. In these embodiments, the first metal layer acts as an efficient surface to spread heat and to transfer heat from its heated surface to the surrounding liquid. The metal backing layer behind the dielectric insulating layer also acts as a surface for spreading heat and for transferring heat from its heater surface to the surrounding liquid. In some embodiments, the LEDs can be packaged or can be placed directly as chips onto the metal interconnect layers that serve to spread and transfer the heat to the thermally conductive liquid. The heat spreading and transfer layers can include the electrical interconnect traces, a thermal interface pad soldered to the associated thermal pad on the LED, or both.

in some embodiments, an alternate heat transfer path may be created that transfers heat from the LED through solder material into a thermal pad, through a dielectric layer, and an underlying mechanical structure that then allows heat spread and transfer to the thermally conductive liquid. While this arrangement creates a higher thermal resistance between the LED and the thermally conductive liquid, it can have a lower thermal resistance than alternative arrangements relying on heat spreading using only a heat sink.

Although a feature may appear to be described in connection with a particular embodiment, one skilled in the art would recognize that various features of the described embodiments may be combined. Moreover, aspects described in connection with an embodiment may stand alone.

What is claimed is:

1. A light-emitting diode (LED) bulb comprising:
a base;
a shell connected to the base;
a thermally conductive liquid held within the shell;
one or more support structures disposed within the shell; and
one or more LEDs mounted to the one or more support structures and immersed in the thermally conductive liquid,
wherein the one or more LEDs each comprise a semiconductor die having at least one light-emitting interface, the one or more LEDs configured to emit light from the at least one light-emitting interface directly into the thermally conductive liquid.

2. The LED bulb of claim 1, wherein the LED bulb omits a lens disposed between the at least one light-emitting interface and the thermally conductive liquid.

3. The LED bulb of claim 1, wherein the semiconductor die of each of the one or more LEDs is directly mounted to the one or more support structures.

4. The LED bulb of claim 1, wherein the one or more support structures includes a flexible circuit, and the semiconductor die of each of the one or more LEDs is directly mounted to the flexible circuit.

5. The LED bulb of claim 1, wherein the one or more support structures includes a flexible circuit, a plurality of the one or more LEDs are electrically connected to a flexible circuit, and the plurality of LEDs are electrically connected together through the flexible circuit.

6. The LED bulb of claim 5, wherein the flexible circuit comprises a thermally conductive material, and wherein the flexible circuit is thermally coupled to the thermally conductive liquid.

7. The LED bulb of claim 5, wherein the flexible circuit forms a cylindrical or conical shape and the plurality of LEDs are arranged in a radial pattern.

8. The LED bulb of claim 1, wherein the one or more support structures comprises a laminate support structure, and the semiconductor die of each of the one or more LEDs is directly mounted to the laminate support structure.

9. The LED bulb of claim 1, wherein the one or more support structures comprises a laminate support structure, a plurality of the one or more LEDs are electrically connected to the laminate support structure, and the plurality of LEDs are electrically connected together through the laminate support structure.

10. The LED bulb of claim 9, wherein the laminate support structure forms a cylindrical or conical shape, and the plurality of LEDs are arranged in a radial pattern.

11. The LED bulb of claim 1, wherein a plurality of the one or more LEDs are electrically coupled together by one or more wire bonds.

12. The LED bulb of claim 11, wherein the one or more wire bonds comprise a thermally conductive material, and wherein the one or more wire bonds are thermally coupled to the thermally conductive liquid.

13. The LED bulb of claim 1, wherein the semiconductor die of at least one of the one or more LEDs is mounted to an encapsulent, and least one light-emitting interface of the semiconductor die is coated with a phosphor material.

14. The LED bulb of claim 1, wherein the one or more LEDs are configured to emit light having a first predicted color when emitting light directly into the thermally conductive liquid, wherein the first predicted color is different than a second predicted color associated with a light emission directly into an air medium.

15. A light-emitting diode (LED) bulb comprising:
a base;
a shell connected to the base;
a thermally conductive liquid held within the shell;
one or more support structures disposed within the shell; and
one or more LEDs mounted to the one or more support structures and immersed in the thermally conductive liquid,
wherein the one or more LEDs each comprise a semiconductor die having at least one light-emitting interface, the one or more LED configured to emit light from the at least one light-emitting interface into the thermally conductive liquid without passing through an intermediary optical element.

16. The LED bulb of claim 15, wherein the intermediary optical element is a lens.

17. The LED bulb of claim 15, wherein the semiconductor die of each of the one or more LEDs is directly mounted to the one or more support structures.

18. The LED bulb of claim 15, wherein the one or more support structures includes a flexible circuit, and the semiconductor die of each of the one or more LEDs is directly mounted to the flexible circuit.

19. The LED bulb of claim 15, wherein the one or more support structures includes a flexible circuit, a plurality of the one or more LEDs are electrically connected to the flexible circuit, and the plurality of LEDs are electrically connected together through the flexible circuit.

20. The LED bulb of claim 19, wherein the flexible circuit comprises a thermally conductive material, and wherein the flexible circuit is thermally coupled to the thermally conductive liquid.

21. The LED bulb of claim 19, wherein the flexible circuit forms a cylindrical or conical shape, and the plurality of LEDs are arranged in a radial pattern.

22. The LED bulb of claim 15, wherein the one or more support structures comprise a laminate support structure, and the semiconductor die of each of the one or more LEDs is directly mounted to the laminate support structure.

23. The LED bulb of claim 15, wherein the one or more support structures comprises a laminate support structure, a plurality of the one or more LEDs are electrically connected to the laminate support structure, and the plurality of LEDs are electrically connected together through the laminate support structure.

24. The LED bulb of claim 23, wherein the laminate support structure forms a cylindrical or conical shape and the plurality of LEDs are arranged in a radial pattern.

25. The LED bulb of claim 15, wherein a plurality of the one or more LEDs are electrically coupled together by one or more wire bonds.

26. The LED bulb of claim 25, wherein the one or more wire bonds comprise a thermally conductive material, and wherein the one or more wire bonds are thermally coupled to the thermally conductive liquid.

27. The LED bulb of claim 15, wherein the semiconductor die of at least one of the one or more LEDs is mounted to an encapsulent, and least one light-emitting interface of the semiconductor die is coated with a phosphor material.

28. The LED bulb of claim 15, wherein the one or more LEDs are configured to emit light having a first predicted color when emitting light directly into the thermally conductive liquid, wherein the first predicted color is different than a second predicted color associated with a light emission directly into an air medium.

29. A method of making a light-emitting diode (LED) bulb, the method comprising:
obtaining a base, a shell, one or more LEDs, and one or more support structures;
attaching the one or more support structures to the base;
attaching the one or more LEDs to the one or more support structures;
connecting the shell to the base, wherein the one or more support structures are disposed within the shell; and
filling the shell with a thermally conductive liquid, wherein the one or more LEDs are immersed in the thermally conductive liquid, and wherein the one or more LEDs each comprise a semiconductor die having at least one light-emitting interface, the one or more LEDs configured to emit light from the at least one light-emitting interface directly into the thermally conductive liquid.

30. The method of claim 29, wherein the LED bulb omits a lens disposed between the at least one light-emitting interface and the thermally conductive liquid.

31. The method of claim 29, wherein the semiconductor die of each of the one or more LEDs is directly mounted to the one or more support structures.
